(19) United States
(12) Patent Application Publication
(10) Pub. No.: US 2006/0148185 A1
(43) Pub. Date: Jul. 6, 2006

(54) Method for manufacturing high voltage transistor

(76) Inventor: Yong Wook Shin, Gwangju-city (KR)

Correspondence Address: MCKENNA LONG & ALDRIDGE LLP;Song K. Jung, 1900 K. Street, N.W., Washington, DC, 20006, US

(21) Appl. No.: 11/320,727

(22) Filed: Dec. 30, 2005

(30) Foreign Application Priority Data
Dec. 31, 2004 (KR) P 2004-0117848

(51) Int. Cl. H01L 21/336; H01L 21/425

(52) U.S. Cl. 438/307; 438/531; 438/306; 438/301; 438/199

(57) ABSTRACT

A method for manufacturing a high voltage transistor is disclosed. The method includes sequentially forming gate oxide films, polysilicon layers, and silicon nitride films on a semiconductor substrate; patterning the silicon nitride films, the polysilicon layers, and the gate oxide films using photolithographic and isotropic etching processes to form nitride film shades and polysilicon gate electrodes; implanting impurity ions into the substrate using the nitride film shades as protective barriers; performing an annealing process to form source and drain diffusion regions of a double diffusion structure; and removing the nitride film shades. Therefore, since the silicon nitride films are used as the protective barriers during impurity ion implantation, the source and drain diffusion regions can be formed in a double diffusion drain junction structure without forming a space oxide film. Also, the source and drain diffusion regions of the double diffusion drain junction structure can be stably formed by one pattern process and one ion implantation process.

This application claims the benefit of the Korean Patent Application No. P2004-0117848, filed on Dec. 31, 2004, which is hereby incorporated by reference for all purposes as if fully set forth herein.

### BACKGROUND OF THE INVENTION

1. Field of the Invention

The present invention relates to a method for manufacturing a semiconductor device for a high voltage transistor, and more particularly, to a method for manufacturing a high voltage transistor, in which a double diffusion drain junction structure in source and drain diffusion regions is formed by one pattern process and one ion implantation process without forming a space oxide film.

2. Discussion of the Related Art

An integrated circuit requires a high voltage control device to directly control an external system that employs a high voltage. The high voltage control device is directly applied with the high voltage of the external system. That is, a high voltage semiconductor device which can be used in a circuit that requires a high breakdown voltage is needed.

An integrated circuit includes a complementary metal oxide semiconductor (CMOS) in which a P-channel MOS and an N-channel MOS are provided in one circuit to serve as a unit transistor. The CMOS is advantageous because of its low power consumption. A semiconductor device comprised of a high voltage CMOS transistor is manufactured similarly to a method for manufacturing a general CMOS transistor. The method for manufacturing the semiconductor will be described in detail based on a double structure in which two wells are formed on a substrate.

First, as shown in FIG. 1A, an N-well 12 and a P-well 14 are formed on a substrate by a well formation process. A PMOS is formed in the N-well 12 while an NMOS is formed in the P-well 14. The N-well 12 and the P-well 14 are formed by respectively implanting an N type dopant and a P type dopant into the substrate through high energy ion implantation and diffusing them at high temperature. In the high voltage CMOS transistor, the wells should be formed more deeply than those of a CMOS transistor based on a general voltage. Next, an isolation process is required to normally operate the transistor. The isolation process is performed by ion implantation and a local oxidation of silicon (LOCOS) process for formation of a field oxide film 16.

After the field oxide film 16 is formed, a thin oxide film is grown by an oxidation process and a polysilicon is immediately deposited thereon. Then, the polysilicon layer is etched by forming a pattern using a mask so that gate oxide films 22a and 22b and gate electrodes 24a and 24b are respectively patterned in the PMOS region and the NMOS region. The gate oxide films 22a and 22b and the gate electrodes 24a and 24b are shown in FIG. 1B.

Subsequently, other terminals of the transistor are formed. That is, to form source and drain regions 26a for PMOS in the N-well 12, the P-well 14 is masked by a photoresist (not shown). Then, the source and drain regions 26a for PMOS are formed in the N-well 12 by ion implantation of a P type dopant such as B and annealing. By contrast, to form source and drain regions 26b for NMOS in the P-well 14, the N-well 12 is masked by a photoresist (not shown). Then, the source and drain regions 26b for NMOS are formed in the P-well 14 by ion implantation of an N type dopant such as P. Annealing is then performed.

Since the source and drain junction of the high voltage transistor is operated at high voltage, a double diffusion drain junction structure is formed to obtain a high breakdown voltage.

To this end, lightly doped layers having the same conductive type as that of the drain region are formed by implanting minor impurity ions below the drain region. The source and drain regions 26a and 26b of the N-well 12 and P-well 14 are formed by minor impurity ion implantation. That is, when the minor impurity ions are diffused by annealing after minor impurity ion implantation, the lightly doped regions 26a and 26b into which the impurity ions are diffused are formed below the gate.

As described above, after the lightly doped source and drain regions 26a and 26b are respectively formed in the N-well 12 and the P-well 14, heavily doped source and drain regions are formed. Before the heavily doped source and drain regions are formed, space oxide films 28a are respectively formed at sidewalls of polysilicon layers 24a and 24b for gate electrodes to avoid degradation of the transistor.

Referring to FIG. 1C, after the lightly doped source and drain regions 26a and 26b are respectively formed in the N-well 12 and the P-well 14, the space oxide films 28a are formed at sidewalls of the gate electrodes 24a and 24b. Referring to FIG. 1D, after the space oxide films 28a are formed, the heavily doped source and drain regions 27a and 27b are respectively formed in the N-well 12 and the P-well 14 by ion implantation and annealing. The heavily doped source and drain regions 27a and 27b are formed similarly to the formation of the lightly doped source and drain regions 26a and 26b. Either the N-well 12 or the P-well 14 is masked by a photoresist. Then, ions are implanted into the opened well and annealing is performed therein, so that the heavily doped source and drain regions are formed. In the high voltage CMOS transistor, it is important how the position of the junction is overlapped with a portion below the gate electrode. In a particular case, the high voltage transistor can be operated by forming the junction without being overlapped with the portion below the gate electrode.

Next, the process for protecting the transistor and externally connecting the transistor is performed. That is, after the transistor is respectively formed in the wells 12 and 14, an oxide film or a dielectric film such as BPSG is formed. Processes for forming a contact hole and a metal layer are formed to externally connect four terminals of the transistor, so that the high voltage CMOS transistor is completely manufactured.

In the aforementioned method for manufacturing the high voltage CMOS transistor, to form the double diffusion drain junction structure, the process of forming the lightly doped source and drain regions 26a and 26b, the process of forming the space oxide films 28a, and the process of forming the heavily doped source and drain regions 27a and 27b are performed. Therefore, the processes of manufacturing the semiconductor device become complicated, thereby reducing yield.

### SUMMARY OF THE INVENTION

Accordingly, the present invention is directed to a method for manufacturing a high voltage transistor, which substantially obviates one or more problems due to limitations and disadvantages of the related art.

An advantage of the present invention is to provide a method for manufacturing a high voltage transistor, in which source and drain diffusion regions of a double diffusion drain junction structure are stably formed by one pattern process and one ion implantation process. This is accomplished by forming silicon nitride films having a width greater than that of polysilicon gate electrodes formed below the silicon nitride films to serve as protective films during impurity ion implantation.

Another advantage of the present invention is to provide a method for manufacturing a high voltage transistor, in which a double diffusion drain junction structure is formed without forming a space oxide film so that polysilicon gate electrodes have a width greater than that of a related art polysilicon gate electrode. This increases a free design in the sizes of the gate electrode and the transistor and reduces manufacturing costs.

Additional features and advantages of the invention will be set forth in the description which follows, and in part will be apparent from the description, or may be learned by practice of the invention. The objectives and other advantages of the invention will be realized and attained by the method particularly pointed out in the written description and claims hereof as well as the appended drawings.

To achieve these and other advantages and in accordance with the purpose of the invention, as embodied and broadly described, a method for manufacturing a high voltage transistor according to the present invention includes the steps of a) sequentially forming gate oxide films, polysilicon layers, and silicon nitride films on a semiconductor substrate, b) patterning the silicon nitride films, the polysilicon layers, and the gate oxide films using photolithographic and isotropic etching processes to form nitride film shades and polysilicon gate electrodes, c) implanting impurity ions into the substrate using the nitride film shades as protective barriers, d) performing an annealing process to form source and drain diffusion regions of a double diffusion structure, and e) removing the nitride film shades.

Therefore, since the silicon nitride films are used as the protective barriers during impurity ion implantation, the source and drain diffusion regions can be formed in a double diffusion drain junction structure without forming a space oxide film. Also, the source and drain diffusion regions of the double diffusion drain junction structure can be stably formed by one pattern process and one ion implantation process.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiment(s) of the invention and together with the description serve to explain the principles of the invention. In the drawings:

FIG. 1A to FIG. 1D illustrate a related art method for manufacturing a high voltage CMOS transistor; and

FIG. 2A to FIG. 2D illustrate a method for manufacturing a high voltage CMOS transistor according to the present invention.

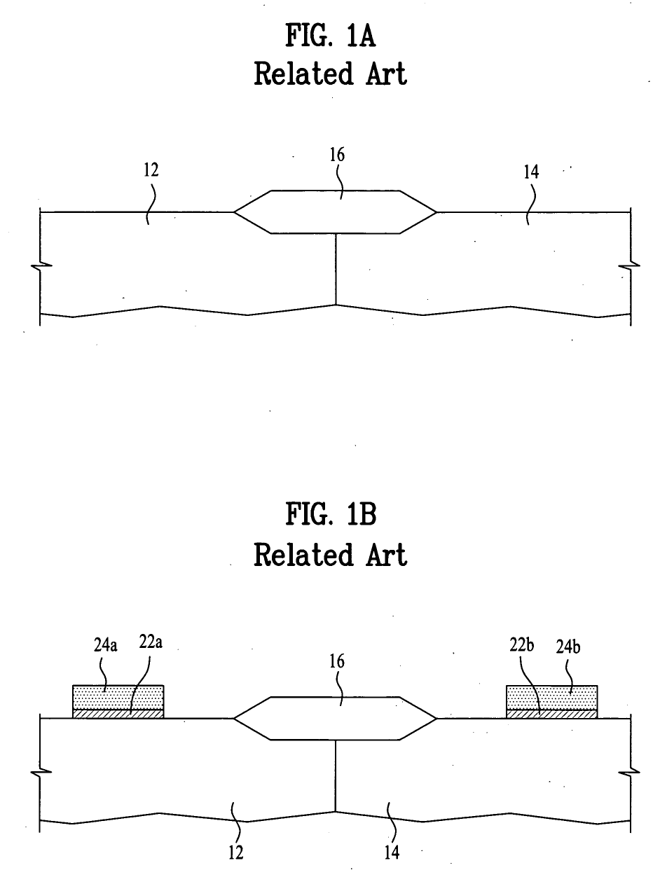

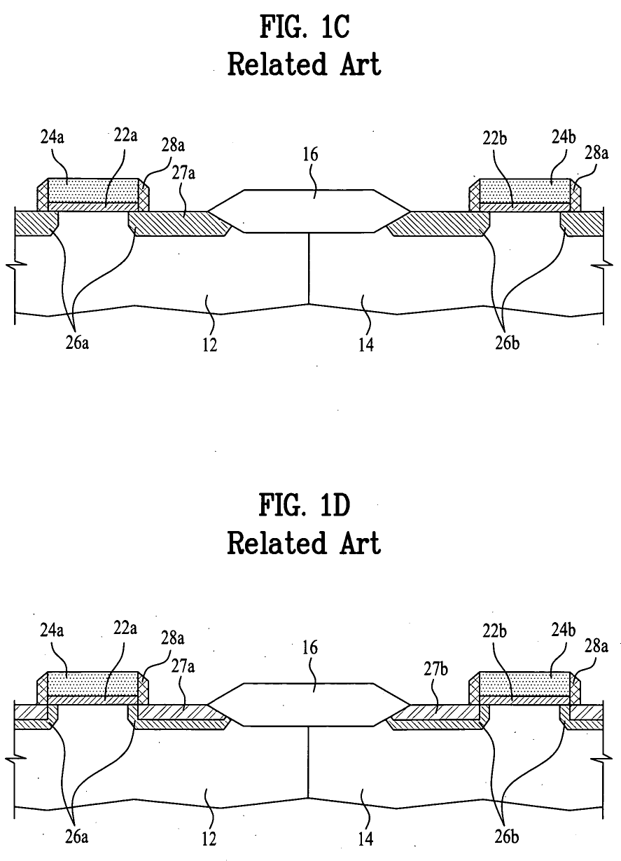

### DETAILED DESCRIPTION OF THE INVENTION

Reference will now be made in detail to embodiments of the present invention, examples of which are illustrated in the accompanying drawings. Wherever possible, the same reference numbers will be used throughout the drawings to refer to the same or like parts.

A method for manufacturing a high voltage CMOS transistor according to the present invention will be described.

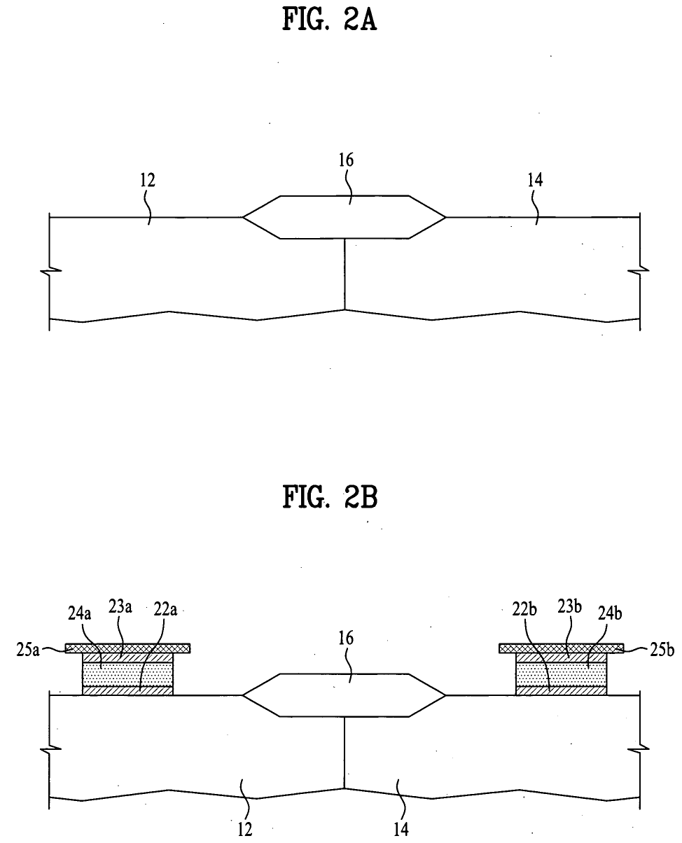

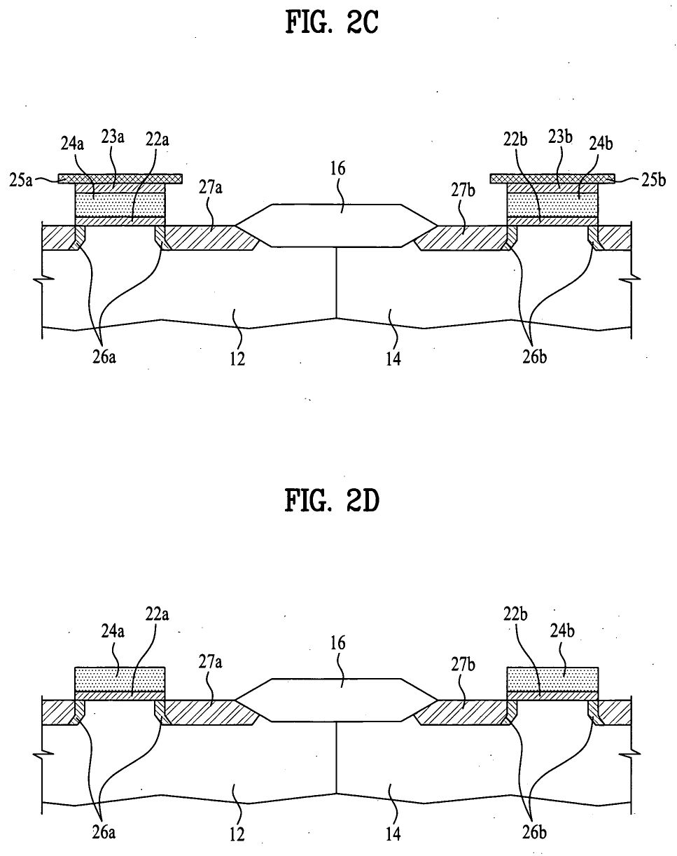

First, a method for forming two wells on a semiconductor substrate is performed. That is, as shown in FIG. 2A, an N-well 12 and a P-well 14 are formed on the semiconductor substrate by a well formation process. A PMOS is formed in the N-well 12 while an NMOS is formed in the P-well 14. The N-well 12 and the P-well 14 are formed by respectively implanting an N type dopant and a P type dopant into the substrate through high energy ion implantation and diffusing them at high temperature. In the high voltage CMOS transistor, the wells should be formed more deeply than those of a CMOS transistor based on a general voltage. Next, a field oxide film 16 is formed by a LOCOS process to normally operate the transistor.

Then, gate oxide films, which are insulating films of a gate to be used as a switch of the transistor, are formed by an oxidation process. Polysilicon layers for gates are immediately deposited on the gate oxide films to avoid contamination. Then, silicon nitride films are formed on the polysilicon layers. The silicon nitride films serves as protective barriers that selectively stop impurity ions for source and drain diffusion regions.

Oxide films are formed before the silicon nitride films are formed on the polysilicon layers. The oxide films serve as buffer films that prevents the nitride films from applying stress to the polysilicon layers.

After the silicon nitride films (or buffer film and silicon nitride film) are formed on the polysilicon layers, the gate oxide films, the polysilicon layers, and the silicon nitride films (or buffer film or silicon nitride film) are patterned by photolithographic and etching processes. The polysilicon layers to be used as the gate electrodes may be patterned to have a width twice greater than that of a general gate electrode. In the present invention, since no space oxide film is formed, the transistor can be formed in the same size as that of the related art transistor even if the polysilicon gate electrodes have a great width as described above.

The gate oxide films 22a and 22b, polysilicon gate electrodes 24a and 24b, the buffer oxide films 23a and 23b, and the silicon nitride films 25a and 25b are shown in FIG. 2B. The above pattern may be formed using isotropic etching, and preferably wet etching. Thus, downward etching of the silicon nitride films and lateral etching of the silicon nitride films are uniformly maintained. Since the silicon nitride films are formed to be greater than the polysilicon gate electrodes 24a and 24b using isotropic etching, cap shaped nitride film shades 25a and 25b are formed on the polysilicon gate electrodes 24a and 24b.

Next, impurity ion implantation is performed to form source and drain diffusion regions of the high voltage CMOS transistor. Either the N-well 12 or the P-well 14 is masked by a photoresist (not shown). Then, ions are implanted into the opened well and annealing is performed therein, so that the source and drain regions are formed.

The source and drain regions 27a and 27b formed in the wells 12 and 14 are shown in FIG. 2C. The source and drain regions 27a and 27b are formed by impurity ion implantation using the nitride film shades 25a and 25b as protective barriers. Annealing is then performed.

The impurity ions are implanted into the wells such that they are away from the gates 24a and 24b due to the nitride film shades 25a and 25b extending to both sides of the gate pattern in a cap shape. The heavily doped source and drain diffusion regions 27a and 27b are formed by the impurity ions implanted to be away from the gates 24a and 24b due to the nitride film shades 25a and 25b.

The impurity ions are implanted into the wells through the nitride film shades 25a and 25b. The impurity ions may partially be stopped by the nitride film shades 25a and 25b. Therefore, a small amount of impurity ions are implanted in the vicinity of the gate electrodes 24a and 24b due to the nitride film shades 25a and 25b. For this reason, the small amount of impurity ions is not deeply implanted into the wells. Therefore, the lightly doped source and drain diffusion regions 26a and 26b are formed.

In the related art, the process of implanting minor impurity ions, the process of forming the space oxide film, and the process of implanting main impurity ions are required to form a double diffusion drain junction. To this end, the patterning process, the process of forming oxide, the ion implantation process, and the annealing process are repeatedly required. However, in the present invention, the double diffusion drain junction structure can be stably formed without forming the space oxide film.

Next, the nitride film shades 25a and 25b and the buffer oxide films 23a and 23b formed on the polysilicon gate electrodes 24a and 24b are removed. Wet etching may be used. The polysilicon gate electrodes having no space oxide film are shown in FIG. 2D.

To more stably form the double diffusion source and drain junction, impurity ion implantation may additionally be performed after the nitride film shades are removed. Impurity ions may be implanted into the source and drain regions by low energy ion implantation so that the junction stably overlapped with a portion below the polysilicon layers used as the gate electrodes can be formed.

After the insulating film is formed to protect the transistor, processes for forming a contact hole and a metal layer are performed to externally connect each terminal of the transistor, so that the semiconductor device is completely manufactured.

As described above, the method for manufacturing a high voltage transistor according to the present invention has the following advantages.

The source and drain diffusion regions of a double diffusion drain junction structure are stably formed by one pattern process and one ion implantation process. This is accomplished by additionally forming the silicon nitride films on the polysilicon gates to serve as the protective films during impurity ion implantation. Thus, it is possible to simplify the processes of manufacturing the semiconductor device.

In addition, since the concentration of impurity ions in a region where the gate electrodes are overlapped with the source and drain diffusion regions can be controlled by controlling the size of the pattern of the silicon nitride films formed on the gate electrodes, it is possible to minimize hot carrier effect that degrades the transistor.

Further, since the double diffusion drain junction structure is formed without forming the space oxide film, the polysilicon gate electrodes are formed to have a width greater than that of the related art polysilicon gate electrode. Thus, it is possible to increase a free design in the sizes of the gate electrode and the transistor and reduce the manufacturing cost even in cases where the mask for the gate electrode has a large size.

It will be apparent to those skilled in the art that various modifications and variation can be made in the present invention without departing from the spirit or scope of the inventions. Thus, it is intended that the present invention cover the modifications and variations of this invention provided they come within the scope of the appended claims and their equivalents.

What is claimed is:

1. A method for manufacturing a high voltage transistor comprising the steps of:
a) sequentially forming gate oxide films, polysilicon layers, and silicon nitride films on a semiconductor substrate;
b) patterning the silicon nitride films, the polysilicon layers, and the gate oxide films using photolithographic and isotropic etching processes to form nitride film shades and polysilicon gate electrodes;
c) implanting impurity ions into the substrate using the nitride film shades as protective barriers;
d) performing an annealing process to form source and drain diffusion regions of a double diffusion structure; and
d) removing the nitride film shades.

2. The method according to claim 1, wherein step a) includes forming buffer oxide films between the polysilicon layers and the silicon nitride films.

3. The method according to claim 1, wherein the isotropic etching process in step b) is a wet etching process.

4. The method according to claim 1, wherein the nitride film shades formed in step b) have a width greater than that of the polysilicon gate electrodes.

5. A high voltage transistor manufactured by the method according to claim 1.
